(19) United States
(12) Patent Application Publication
(10) Pub. No.: US 2026/0280169 A1
(43) Pub. Date: Sep. 17, 2026

(54) TERMINAL ASSEMBLY AND LIQUID-COOLED CHARGING SYSTEM

(71) Applicant: Luxshare Precision Industry (Jiangsu)Co.,Ltd., Changzhou City (CN)

(72) Inventors: Peiquan LIN, Changzhou City (CN); Peiwei LIN, Changzhou City (CN); Xiangfeng SHEN, Changzhou City (CN); Xingran TANG, Changzhou City (CN); Yunbo LINGHU, Changzhou City (CN)

(73) Assignee: Luxshare Precision Industry (Jiangsu)Co.,Ltd., Changzhou City (CN)

(21) Appl. No.: 19/337,035

(22) Filed: Sep. 23, 2025

(30) Foreign Application Priority Data
Mar. 13, 2025 (CN) 202510302512.1

(51) Int. Cl. H01R 13/00; B60L 53/16; B60L 53/18; B60L 53/302; H01R 13/52; H05K 5/06; H05K 7/20

(52) U.S. Cl. CPC H01R 13/005; H01R 13/5202; H05K 5/061; H05K 7/20145; H05K 7/20272; B60L 53/16; B60L 53/18; B60L 53/302; H01R 2201/26

(57) ABSTRACT

Provided are a terminal assembly and a liquid-cooled charging system. The terminal assembly includes a conductive terminal, a cable, and a cooling cavity body. The conductive terminal has a plug-in end and a connecting end. The cable is electrically connected to the connecting end. The cooling cavity body has a cooling inlet, one end of the cooling cavity body is sealingly sleeved on the connecting end, and the other end of the cooling cavity body is sealingly sleeved on an end of the cable for connecting the connecting end. The conductive terminal, the cable, and the cooling cavity body mate with one another to form a cooling cavity communicating with the cooling inlet, and a cooling medium is disposed in the cooling cavity.

### CROSS-REFERENCE TO RELATED APPLICATION(S)

This application claims priority to Chinese Patent Application No. 202510302512.1 filed on Mar. 13, 2025, the disclosure of which is incorporated herein by reference in its entirety.

### TECHNICAL FIELD

The present disclosure relates to the field of charging technologies with liquid cooling and, in particular, to a terminal assembly and a liquid-cooled charging system.

### BACKGROUND

A new energy electric vehicle needs to be charged through a charging gun. The charging gun has a conductive terminal, and the conductive terminal is inserted into a slot of the charging port of the new energy electric vehicle to charge the new energy electric vehicle. To improve the charging efficiency, the charging gun generally has relatively large power, and a conductive terminal with a large overload current generates a large amount of heat, resulting in a relatively large temperature rise of the conductive terminal. Moreover, the temperature rise of the conductive terminal directly affects the maximum current of the charging gun and the charging duration of the charging gun. Therefore, the conductive terminal needs to be cooled.

In the related art, the conductive terminal is cooled by disposing a cooling tube on the periphery of the conductive terminal, and a cooling liquid is disposed in the cooling tube. The heat generated by the conductive terminal is first transferred to the cooling tube and then carried away by the cooling liquid in the cooling tube so that the conductive terminal is cooled. However, the contact area between the cooling tube and the conductive terminal is relatively small, resulting in relatively low heat transfer efficiency between the cooling liquid and the conductive terminal, so the cooling liquid cannot carry away the heat on the conductive terminal in time. Furthermore, the charging efficiency of the charging gun is affected, and the charging duration is prolonged. It can be seen that the existing cooling manner for the conductive terminal of the charging gun has relatively low efficiency.

### SUMMARY

A terminal assembly includes a conductive terminal, a cable, and a cooling cavity body.

The conductive terminal has a plug-in end and a connecting end.

The cable is electrically connected to the connecting end.

The cooling cavity body has a cooling inlet, one end of the cooling cavity body is sealingly sleeved on the connecting end, and the other end of the cooling cavity body is sealingly sleeved on an end of the cable for connecting the connecting end.

The conductive terminal, the cable, and the cooling cavity body mate with one another to form a cooling cavity communicating with the cooling inlet, and a cooling medium is disposed in the cooling cavity.

In one embodiment, the cable is provided with a cooling channel, the cooling channel has a channel opening on the surface of the cable, and the channel opening is provided in a portion of the cable located in the cooling cavity body and communicates with the cooling cavity.

In one embodiment, the terminal assembly further includes a support structure disposed in the cooling channel, and the support structure is provided with a support through hole communicating with the cooling channel and is configured to support the cable.

In one embodiment, the connecting end includes a body portion and a connecting portion, the cooling cavity body is sealingly sleeved on the body portion, the body portion, the cable, and the cooling cavity body mate with one another to form the cooling cavity communicating with the cooling inlet, and the connecting portion is located in the cooling cavity.

In one embodiment, a conductive portion is disposed at the end of the cable facing the conductive terminal, the conductive portion and the connecting portion are stacked and electrically connected to each other, and the conductive portion is located in the cooling cavity.

In one embodiment, the cooling cavity body is provided with a mounting hole, a screw hole mating with the mounting hole is provided at the connecting end, the terminal assembly further includes a connecting bolt, and the connecting bolt passes through the mounting hole and is screwed into the screw hole to connect the cooling cavity body to the connecting end.

In one embodiment, the terminal assembly further includes a first sealing assembly, the first sealing assembly is sleeved on the connecting end and is used for sealing a gap between the outer peripheral surface of the connecting end and the inner peripheral surface of the cooling cavity body, and the first sealing assembly is disposed on a side of the connecting bolt facing the cooling cavity.

In one embodiment, a stop portion is provided on the outer peripheral surface of the connecting end, and the stop portion is used for abutting against an end surface of the end of the cooling cavity body to limit a relative position between the cooling cavity body and the conductive terminal.

In one embodiment, the terminal assembly further includes a second sealing assembly, the second sealing assembly is sleeved on the cable and located at the joint between the cable and the cooling cavity body, a limit protrusion is provided on the inner wall of one end of the second sealing assembly, the other end of the second sealing assembly is connected to the cable, a limit groove is provided on the outer wall of the cooling cavity body, and the limit protrusion is engaged in the limit groove.

In one embodiment, the cooling cavity body includes a cavity body, an adapter structure, and a sealing joint, one end of the cavity body is sealingly sleeved on the connecting end, the other end of the cavity body is sealingly sleeved on the cable, and the cavity body, the conductive terminal, and the cable mate with one another to form the cooling cavity.

The adapter structure is connected to a side of the cavity body, the adapter structure has a connecting flow channel communicating with the cooling cavity, the sealing joint is sealingly disposed at a flow channel opening of the connecting flow channel facing away from the cooling cavity, and the cooling inlet is disposed at the sealing joint and communicates with the connecting flow channel.

A liquid-cooled charging system includes the terminal assembly as described above.

### BRIEF DESCRIPTION OF DRAWINGS

To illustrate technical solutions in embodiments of the present disclosure more clearly, the drawings used in the description of the embodiments of the present disclosure are briefly described below. Apparently, the drawings described below illustrate only part of the embodiments of the present disclosure, and those of ordinary skill in the art may obtain other drawings based on the embodiments of the present disclosure and the drawings on the premise that no creative work is done.

FIG. 1 is a first view illustrating the structure of a terminal assembly according to embodiment one of the present disclosure;

FIG. 2 is a second view illustrating the structure of a terminal assembly according to embodiment one of the present disclosure;

FIG. 3 is a sectional view of a terminal assembly according to embodiment one of the present disclosure;

FIG. 4 is an exploded view of a terminal assembly according to embodiment one of the present disclosure;

FIG. 5 is a view illustrating the structure of a conductive terminal according to embodiment one of the present disclosure;

FIG. 6 is a view illustrating the structure of a cooling cavity body according to embodiment one of the present disclosure;

FIG. 7 is a view illustrating the structure of a terminal assembly according to embodiment two of the present disclosure;

FIG. 8 is a view illustrating the structure of a conductive terminal according to embodiment two of the present disclosure;

FIG. 9 is a sectional view of a terminal assembly according to embodiment two of the present disclosure;

FIG. 10 is a view illustrating the structure of a liquid-cooled charging system according to embodiment three of the present disclosure; and

FIG. 11 is a view illustrating the structure of part of a liquid-cooled charging system according to embodiment three of the present disclosure.

### DETAILED DESCRIPTION

To make the solved technical problems, adopted technical solutions, and achieved technical effects of the present disclosure more apparent, the technical solutions of the present disclosure are further described below in conjunction with drawings and embodiments. It is to be understood that the embodiments described herein are intended to explain the present disclosure and not to limit the present disclosure. Additionally, it is to be noted that for ease of description, only part, not all, related to the present disclosure is illustrated in the drawings.

It is to be noted that similar reference numerals and letters represent similar items in the drawings. Therefore, once an item is defined in one drawing, the item no longer needs to be defined and interpreted in the subsequent drawings.

In the description of the present disclosure, the terms “joined”, “connected”, and “secured” are to be understood in a broad sense unless otherwise expressly specified and limited. For example, the term “connected” may refer to “securely connected”, “detachably connected”, or “integrated”, may refer to “mechanically connected” or “electrically connected”, may refer to “connected directly” or “connected indirectly through an intermediary”, or may refer to “connected inside two elements” or “an interaction relation between two elements”. For those of ordinary skill in the art, specific meanings of the preceding terms in the present disclosure may be understood based on specific situations.

In the present disclosure, unless otherwise expressly specified and limited, when a first feature is described as “above” or “below” a second feature, the first feature and the second feature may be in direct contact, or the first feature and the second feature may be in contact via another feature between the two features instead of being in direct contact. Moreover, when the first feature is described as being “on”, “above”, or “over” the second feature, the first feature is right on, above, or over the second feature, the first feature is obliquely on, above, or over the second feature, or the first feature is simply at a higher level than the second feature. When the first feature is described as being “under”, “below”, or “underneath” the second feature, the first feature is right under, below, or underneath the second feature, the first feature is obliquely under, below, or underneath the second feature, or the first feature is simply at a lower level than the second feature. In the description of this embodiment, “multiple” means two or more unless otherwise specified.

In the description of this embodiment, orientations or position relations indicated by terms such as “center”, “longitudinal”, “transverse”, “length”, “width”, “thickness”, “up”, “down”, “front”, “rear”, “left”, “right”, “vertical”, “horizontal”, “top”, “bottom”, “in”, “out”, “clockwise”, “counterclockwise”, “axial”, “radial”, and “circumferential” are based on the drawings. These orientations or position relations are intended only to facilitate description and simplify operations and not to indicate or imply that a device or component referred to must have such particular orientations or must be configured or operated in such particular orientations. Thus, these orientations or position relations are not to be construed as limiting the present disclosure. Additionally, the terms “first” and “second” are used for distinguishing between descriptions and have no special meanings.

It is to be noted that when an element is described as being “secured to” or “disposed on” another element, the element may be directly on the particular element, or an intervening element may be on the particular element.

The technical solutions of the present disclosure are further described below in conjunction with the drawings and the embodiments.

### Embodiment One

This embodiment provides a terminal assembly. The terminal assembly may be used in a liquid-cooled charging system such as a charging gun and has relatively high cooling efficiency. Thus, a charging gun using the terminal assembly and a liquid-cooled charging system using the terminal assembly have relatively high charging efficiency.

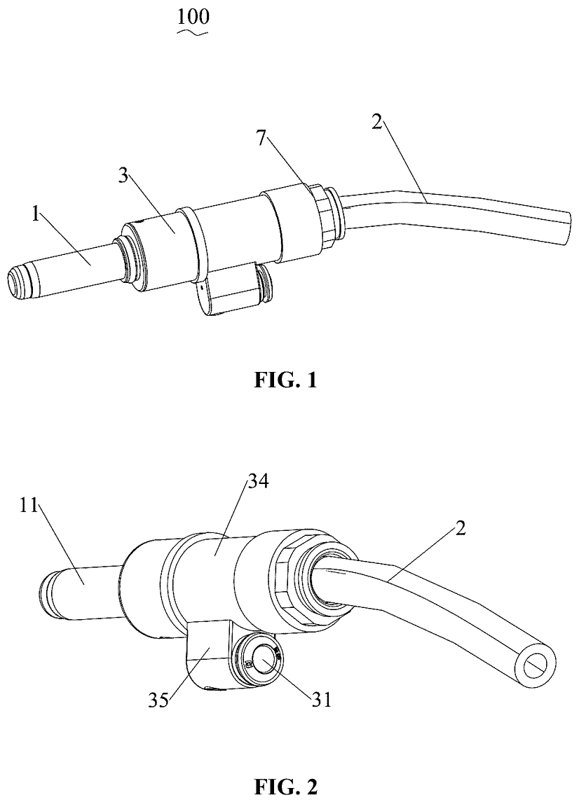

Exemplarily, as shown in FIGS. 1 to 6, the terminal assembly 100 includes a conductive terminal 1, a cable 2, and a cooling cavity body 3. The conductive terminal 1 has a plug-in end 11 and a connecting end 12. The plug-in end 11 and the connecting end 12 are the two ends of the conductive terminal 1 in the axial direction of the conductive terminal 1. The plug-in end 11 is configured to be plugged into a slot of a vehicle or another to-be-charged device. The connecting end 12 is configured to be electrically connected to the cable 2. For example, one end of the cable 2 is electrically connected to the connecting end 12.

In some embodiments, as shown in FIGS. 1 and 2, the plug-in end 11 in this embodiment is cylindrical.

As shown in FIG. 2, the cooling cavity body 3 has a cooling inlet 31. The cooling inlet 31 communicates with a cooling source, and a cooling medium in the cooling source enters the cooling cavity body 3 through the cooling inlet 31. One end of the cooling cavity body 3 is sealingly sleeved on the connecting end 12 and the other end of the cooling cavity body 3 is sealingly sleeved on the end of the cable 2 for connecting the connecting end 12 so that the conductive terminal 1, the cable 2, and the cooling cavity body 3 mate with one another to form a cooling cavity 10 communicating with the cooling inlet 31. The cooling medium is disposed in the cooling cavity 10 and used for cooling the conductive terminal 1 and the cable 2, thus avoiding an excessively high temperature of the conductive terminal 1.

Exemplarily, the cooling medium may be a liquid or a gas, which is not limited in this embodiment. The cooling medium may be a common cooling liquid in the related art or may be cooling oil in the related art, which is not limited in this embodiment.

In one or more embodiments, the material of the cooling cavity body 3 may be a metal material or a non-metal material, which is not limited in this embodiment. When the cooling cavity body 3 is made of the metal material, on the one hand, the cooling cavity body 3 has relatively high structural strength and pressure resistance; on the other hand, the cooling cavity body 3 also has relatively high sealing performance, reducing the risk of leakage of the cooling medium.

In the terminal assembly 100 provided in this embodiment, the connecting end 12 of the conductive terminal 1 is configured to be electrically connected to the cable 2 so that the conduction between the cable 2 and the conductive terminal 1 is implemented. One end of the cooling cavity body 3 is sealingly sleeved on the connecting end 12 and the other end of the cooling cavity body 3 is sealingly sleeved on the end of the cable 2 for connecting the connecting end 12 so that the conductive terminal 1, the cable 2, and the cooling cavity body 3 can mate with one another to form the cooling cavity 10 and the cooling medium in the cooling cavity 10 can be in direct contact with the connecting end 12 and the portion of the cable 2 for connecting the connecting end 12. Thus, the cooling medium can directly absorb the heat on the conductive terminal 1 and the cable 2 to carry away the heat on the conductive terminal 1 and the cable 2 in time, and the heat transfer efficiency between the cooling medium and each of the conductive terminal 1 and the cable 2 is improved so that the temperature of the terminal assembly 100 is not excessively high. Furthermore, the charging efficiency of the liquid-cooled charging system using the terminal assembly 100 is not limited, and the charging duration is shortened.

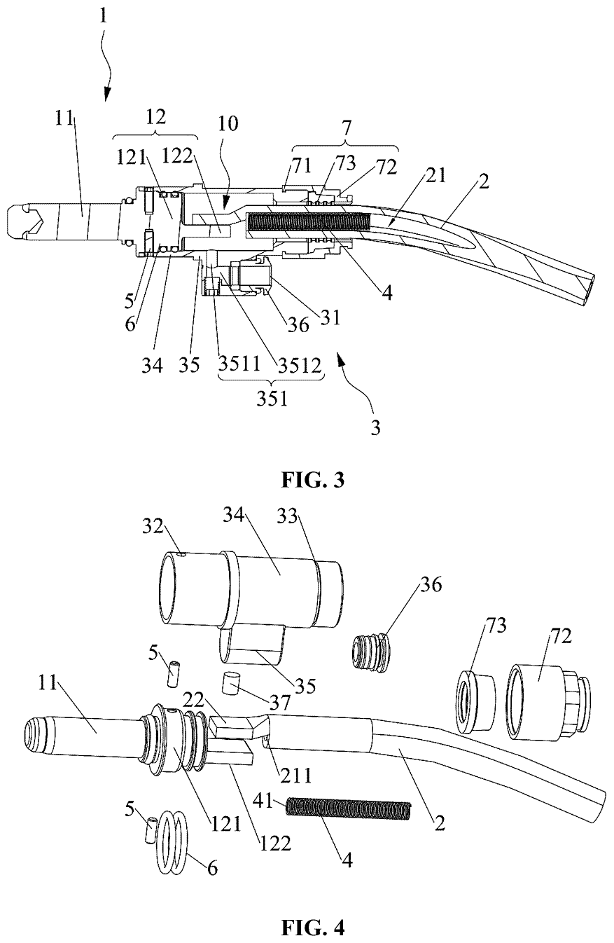

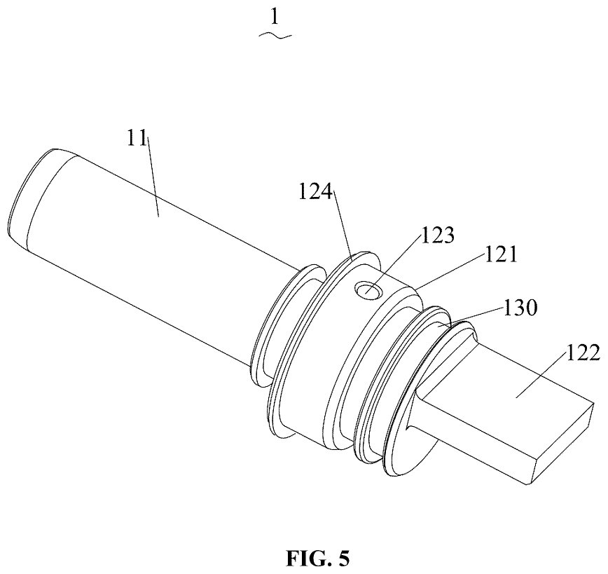

To avoid the problem that the cable 2 has an excessively high temperature due to the transmission of a relatively large current, in some embodiments, the cable 2 in this embodiment is a liquid-cooled cable. For example, as shown in FIG. 3, the cable 2 is provided with a cooling channel 21. As shown in FIG. 4, the cooling channel 21 has a channel opening 211 on the surface of the cable 2, and the channel opening 211 is provided in a portion of the cable 2 located in the cooling cavity body 3 and communicates with the cooling cavity 10. In this manner, the cooling medium in the cooling cavity 10 can enter the cooling channel 21 through the channel opening 211 and then flow in the cable 2, to carry away heat generated by the cable 2 and perform cooling on the cable 2. The configuration of the cooling channel 21 enables the heating wire in the cable 2 to be in direct contact with the cooling medium, thereby improving the heat exchange efficiency between the cable 2 and the cooling medium and improving the cooling efficiency for the cable 2.

The cooling channel 21 is formed in the cable 2, that is, the cable 2 is designed as a hollow structure. Therefore, the structural strength of the cable 2 is inevitably affected. In this embodiment, to improve the structural strength of the cable 2, for example, the terminal assembly 100 further includes a support structure 4, as shown in FIG. 3 or FIG. 4. The support structure 4 is disposed in the cooling channel 21 and used for supporting the cable 2 to improve the pressure resistance of the cable 2 and the structural strength of the cable 2. For example, to ensure the support effect of the support structure 4, the circumferential outer wall of the support structure 4 abuts against the circumferential inner wall of the cable 2 to prevent the support structure 4 from occupying too much space of the cooling channel 21.

To prevent the support structure 4 from affecting the flow of the cooling medium, the support structure 4 in this embodiment is provided with a support through hole 41 communicating with the cooling channel 21, as shown in FIG. 4. The support through hole 41 is configured to penetrate through the support structure 4 in the axial direction of the cable 2 so that the cooling medium outside an end of the support structure 4 can flow through the support through hole 41 to the outside of the other end of the support structure 4, and the cable cooling channel 21 is not blocked.

It is to be noted that the support structure 4 provided with the support through hole 41 can support the inner wall of the cable 2. Furthermore, the formed cooling channel 21 can have a relatively large cross-sectional size. In addition, with the support of the support structure 4, the space in which the cooling medium flows is not reduced due to bending or squeezing, thereby ensuring the flow rate of the cooling medium and enabling the cooling medium to carry away more heat. For example, an end of the cooling channel 21 facing away from the cooling cavity communicates with the cooling source. In this case, the cooling source, the cooling cavity 10, and the cooling channel 21 form a cooling loop. When the flow rate and flow velocity of the cooling medium in the cooling channel 21 increase, the flow rate and the flow velocity of the cooling medium in the cooling cavity 10 also increase. Thus, the cooling effect on the conductive terminal 1 can be improved, thereby achieving efficient charging of the liquid-cooled charging system using the terminal assembly 100.

In some embodiments, the support structure 4 may be cylindrical, which has a relatively good support effect and is convenient to manufacture. In some other embodiments, as shown in FIG. 4, the support structure 4 may be spiral, which can also have a relatively good support effect.

For example, the support structure 4 may be made of a metal material to ensure the support effect on the cable 2. Of course, it is to be understood that the support structure 4 may be made of a non-metal material, which is not limited in this embodiment.

In some embodiments, to improve the overall structural strength of the conductive terminal 1, the conductive terminal 1 in this embodiment is an integrated structure so that the conductive terminal 1 has relatively high structural strength and can also have relatively low resistance.

With continued reference to FIG. 3 or FIG. 4, the connecting end 12 includes a body portion 121 and a connecting portion 122. The end of the cooling cavity body 3 is sealingly sleeved on the body portion 121, and the body portion 121, the cable 2, and the cooling cavity body 3 mate with one another to form the cooling cavity 10 communicating with the cooling inlet 31. The connecting portion 122 is located in the cooling cavity 10 and is used for connecting the cable 2. The connecting portion 122 of the conductive terminal 1 for connecting the cable 2 is located in the cooling cavity 10. Moreover, the part of the connecting portion 122 connected to the cable 2 is the region where the most heat is generated in the entire terminal assembly 100. Therefore, in this embodiment, the connecting portion 122 is completely immersed in the cooling medium in the cooling cavity 10, thereby increasing the contact area between the connecting portion 122 and the cooling medium. In this manner, the heat transfer efficiency between the connecting portion 122 and the cooling medium is further improved so that the connecting portion 122 is rapidly cooled and an excessively high temperature at the region where the connecting portion 122 is connected to the cable 2 is avoided.

In one or more embodiments, as shown in FIG. 5, the body portion 121 in this embodiment is cylindrical. Cooperatively, one end of the cooling cavity body 3 is also cylindrical to facilitate a sealing connection to the body portion 121 and ensure a sealing effect. The connecting portion 122 in this embodiment is in the shape of a flat block, and the sectional size of the connecting portion 122 is smaller than the sectional size of the body portion 121.

To improve the connection effect between the cable 2 and the connecting portion 122, in a feasible embodiment, as shown in FIG. 4, a conductive portion 22 is disposed at the end of the cable 2 facing the conductive terminal 1. The conductive portion 22 is electrically connected to the connecting portion 122 so that the difficulty in connecting the cable 2 to the conductive terminal 1 is reduced. In some embodiments, the conductive portion 22 and the connecting portion 122 are stacked, that is, the conductive portion 22 is also in the shape of a flat block. In addition, a large surface of the conductive portion 22 is in contact with a large surface of the connecting portion 122 so that the conductive portion 22 and the connecting portion 122 have a relatively large contact area, thereby improving the connection reliability of the conductive portion 22 and the connecting portion 122. It is to be noted that the conductive portion 22 in this embodiment is configured to avoid the channel opening 211. For example, the conductive portion 22 is disposed on a side of the channel opening 211 so that the flow area of the channel opening 211 is not affected and the flow rate of the cooling medium in the cooling channel 21 is ensured.

To further improve the connection effect between the connecting portion 122 and the conductive portion 22, in this embodiment, the connecting portion 122 and the conductive portion 22 are connected to each other through ultrasonic welding, reducing the risk of a connection failure.

The conductive portion 22 in this embodiment is located in the cooling cavity 10 so that the conductive portion 22 can be in direct contact with the cooling medium. Thus, the cooling effect of the cooling medium on the conductive portion 22 is improved, and the risk of an excessively high temperature at the joint between the conductive portion 22 and the connecting portion 122 is reduced, thereby increasing the maximum overcurrent that the terminal assembly 100 can bear. Furthermore, the charging efficiency of the liquid-cooled charging system using the terminal assembly 100 is improved.

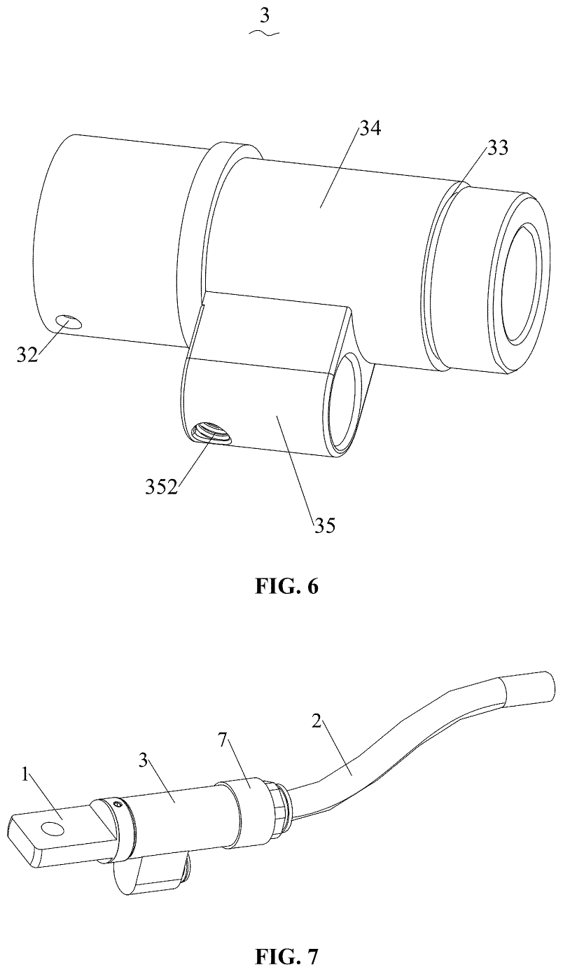

The cooling cavity body 3 may be connected to the conductive terminal 1 in various manners. This embodiment provides a structure for connecting the cooling cavity body 3 to the conductive terminal 1. As shown in FIG. 4 or FIG. 6, the cooling cavity body 3 is provided with a mounting hole 32. As shown in FIG. 5, a screw hole 123 mating with the mounting hole 32 is provided at the connecting end 12 of the conductive terminal 1. In this embodiment, the mounting hole 32 mates with the screw hole 123, which means that the mounting hole 32 and the screw hole 123 are coaxially disposed. Exemplarily, the screw hole 123 is provided on the body portion 121. The terminal assembly 100 further includes a connecting bolt 5. The shank of the connecting bolt 5 passes through the mounting hole 32 and is screwed into the screw hole 123 to connect the cooling cavity body 3 to the connecting end 12. In this manner, the structure for connecting the cooling cavity body 3 to the conductive terminal 1 is relatively simple, convenient to mount, and relatively low in cost. It is to be noted that the head of the connecting bolt 5 is in close contact with the outer wall surface of the cooling cavity body 3 so that the cooling cavity body 3 can be in close contact with the body portion 121 of the conductive terminal 1, thereby improving the sealing performance of the connection between the conductive terminal 1 and the cooling cavity body 3.

In some embodiments, to improve the connection effect between the cooling cavity body 3 and the conductive terminal 1, multiple connecting bolts 5, multiple mounting holes 32, and multiple screw holes 123 are provided in one-to-one correspondence so that multiple connecting points exist between the cooling cavity body 3 and the conductive terminal 1. Thus, the connection reliability between the cooling cavity body 3 and the conductive terminal 1 is further improved.

It is to be understood that the manner in which the cooling cavity body 3 is connected to the conductive terminal 1 is not limited to the case of connecting through the connecting bolt 5. Alternatively, the cooling cavity body 3 is provided with an internal thread, the conductive terminal 1 is provided with an external thread, and the cooling cavity body 3 is directly screwed with the conductive terminal 1. This embodiment does not impose any limitation in this aspect.

A first sealing assembly 6 may be provided such that the sealing performance between the cooling cavity body 3 and the conductive terminal 1 that are connected to each other through the connecting bolt 5 is further improved. Exemplarily, as shown in FIGS. 3 and 4, the terminal assembly 100 further includes the first sealing assembly 6. The first sealing assembly 6 is sleeved on the connecting end 12, for example, the first sealing assembly 6 may be sleeved on the body portion 121. The first sealing assembly 6 is used for sealing a gap between the outer peripheral surface of the connecting end 12 and the inner peripheral surface of the cooling cavity body 3 so that a more sealed cooling cavity 10 can be formed. Thus, the risk of leakage of the cooling medium through the gap between the cooling cavity body 3 and the connecting end 12 is reduced.

In an embodiment, as shown in FIG. 3, the first sealing assembly 6 is disposed on a side of the connecting bolt 5 facing the cooling cavity 10. For example, in the axial direction of the conductive terminal 1, the first sealing assembly 6 is disposed on the side of the connecting bolt 5 adjacent to the cooling cavity 10. In this manner, the cooling medium can be prevented from flowing to be in contact with the connecting bolt 5 through the gap between the cooling cavity body 3 and the conductive terminal 1 and entering the screw hole 123. Thus, the risk is reduced that the cooling medium affects the structural strength of the connecting bolt 5, and the waste of the cooling medium is reduced.

Exemplarily, the first sealing assembly 6 includes at least one sealing ring. The material of the sealing ring is silica gel, rubber, or the like, which is not limited in this embodiment. The first sealing assembly 6 in this embodiment includes two sealing rings. The two sealing rings are spaced apart along the axial direction of the conductive terminal 1.

In one or more embodiments, as shown in FIG. 5, annular sealing grooves 130 are provided on the outer peripheral surface of the body of the conductive terminal 1. The sealing rings are disposed in the sealing grooves 130 to be limited by the sealing grooves 130, thereby avoiding an axial movement of the sealing rings.

To facilitate the mounting of the cooling cavity body 3 to the conductive terminal 1, in an embodiment, as shown in FIG. 5, a stop portion 124 is provided on the outer peripheral surface of the connecting end 12. When the connecting end 12 includes the body portion 121, the stop portion 124 is provided on the body portion 121. The stop portion 124 is used for abutting against an end surface of the end of the cooling cavity body 3 to limit a relative position between the cooling cavity body 3 and the conductive terminal 1. That is, the maximum length to which the conductive terminal 1 extends into the cooling cavity body 3 is limited. In this manner, on the one hand, it can be ensured that the mounting position of the cooling cavity body 3 and the conductive terminal 1 of each terminal assembly 100 is consistent, which facilitates batch manufacturing of terminal assemblies 100. On the other hand, the case where the cooling effect is affected by a relatively small size of the cooling cavity 10 due to an excessively long portion of the conductive terminal 1 inserted into the cooling cavity body 3 can be avoided. In addition, the cooling cavity body 3 abuts against the stop portion 124 so that a sealing structure can be formed. Thus, multiple seals exist between the cooling cavity body 3 and the conductive terminal 1, thereby further improving the sealing effect.

In one or more embodiments, the stop portion 124 is annular to improve the contact area between the stop portion 124 and the cooling cavity body 3 and ensure the stop and positioning effect and the sealing effect.

A sealing structure is also disposed between the cooling cavity body 3 and the cable 2 to ensure the sealing performance of the connection between the cooling cavity body 3 and the cable 2. In one or more embodiments, as shown in FIG. 3 or FIG. 4, the terminal assembly 100 further includes a second sealing assembly 7. The second sealing assembly 7 is sleeved on the cable 2 and located at the joint between the cable 2 and the cooling cavity body 3. The second sealing assembly 7 is used for sealing the gap between the cable 2 and the cooling cavity body 3, further improving the sealing performance of the cooling cavity 10.

In an embodiment, the second sealing assembly 7 includes a sealing plug 72 and a waterproof ring 73 that are both sleeved on the cable 2. The waterproof ring 73 is sandwiched among an end surface of the cooling cavity body 3, the inner wall of the sealing plug, and the outer wall of the cable 2 and has a waterproof and sealing effect. One end of the sealing plug 72 in the axial direction is in close contact with the outer wall of the cable 2, the other end of the sealing plug 72 is in close contact with the outer wall of the cooling cavity body 3, and the middle portion of the sealing plug 72 is in close contact with the outer wall of the waterproof ring 73 so that the cooling and sealing between the cooling cavity body 3 and the cable 2 are implemented with a good sealing effect.

In other embodiments, the second sealing assembly 7 may further include at least one sealing ring sleeved on the cable 2 to achieve the sealing performance.

To limit a relative position between the second sealing assembly 7 and the cooling cavity body 3, in one or more embodiments, as shown in FIG. 3, a limit protrusion 71 is provided on the inner wall of one end of the second sealing assembly 7, and the other end of the second sealing assembly 7 is connected to the cable 2. In addition, as shown in FIG. 6, a limit groove 33 is provided on the outer wall of the cooling cavity body 3, and the limit protrusion 71 is engaged in the limit groove 33. On the one hand, the cable 2 can be connected to the cooling cavity body 3 through the second sealing assembly 7; on the other hand, the relative position between the second sealing assembly 7 and the cooling cavity body 3 can be limited. Thus, the mounting difficulty of the second sealing assembly 7 and the cooling cavity body 3 is reduced, and mounting efficiency is improved.

Exemplarily, when the second sealing assembly 7 includes the waterproof ring 73 and the sealing plug 72, the limit protrusion 71 is provided on the inner wall of the end of the sealing plug 72, and the other end of the sealing plug 72 is connected to the outer wall of the cable 2.

In one or more embodiments, the limit protrusion 71 and the limit groove 33 in this embodiment are both annular so that the limit protrusion 71 can be conveniently engaged into the limit groove 33 without controlling the cooling cavity body 3 and the sealing plug 72 to be at a specific position, thereby further reducing the mounting difficulty of the terminal assembly 100.

One end of the cooling cavity body 3 in the axial direction thereof is connected to the connecting end 12 of the conductive terminal 1 and the other end of the cooling cavity body 3 in the axial direction thereof is connected to the cable 2 so that the cooling inlet 31 of the cooling cavity body 3 needs to be provided on a side of the cooling cavity body. In this embodiment, to facilitate the connection between the cooling inlet 31 and a tube, for example, the cooling cavity body 3 includes a cavity body 34 and an adapter structure 35, as shown in FIGS. 3 and 4. The adapter structure 35 is connected to a side of the cavity body 34, and the adapter structure 35 has a connecting flow channel 351 communicating with the cooling cavity 10. The connecting flow channel 351 communicates with the cooling inlet 31 so that the cooling medium enters the cooling cavity 10 through the connecting flow channel 351. One end of the cavity body 34 is sealingly sleeved on the connecting end 12 and the other end of the cavity body 34 is sealingly sleeved on the cable 2 so that the cavity body 34, the conductive terminal 1, and the cable 2 mate with one another to form the cooling cavity 10. The adapter structure 35 is disposed and the connecting flow channel 351 is provided in the adapter structure 35. Thus, the position of the cooling inlet 31 is relatively flexible so that the connection of the tube is facilitated and the mounting difficulty is reduced.

It is to be noted that the adapter structure 35 and the cavity body 34 in this embodiment have an integrated structure to achieve relatively high structural strength.

In one or more embodiments, as shown in FIG. 3, the connecting flow channel 351 includes a first section 3511 and a second section 3512 arranged at an included angle, and the second section 3512 and the cooling inlet 31 may be coaxially disposed. The flow channel opening of the first section 3511 facing away from the second section 3512 communicates with the cooling cavity 10. In this manner, the extension direction of the second section 3512 may be the axial direction of the cavity body 34. Furthermore, the extension direction of the tube connected to the cooling inlet 31 is substantially the same as the extension direction of the cable 2 so that the space occupied by the liquid-cooled charging system using the terminal assembly 100 in the radial direction is reduced, thereby improving the miniaturization of the liquid-cooled charging system.

In some embodiments, the cooling cavity body 3 further includes a sealing joint 36. The sealing joint 36 is sealingly disposed at a flow channel opening of the connecting flow channel 351 facing away from the cooling cavity 10, and the cooling inlet 31 is disposed at the sealing joint 36 and communicates with the connecting flow channel 351. The sealing joint 36 is provided so that the connection and communication between the cooling cavity body 3 and the tube can be facilitated. In this embodiment, the axial direction of the sealing joint 36 is the same as the axial direction of the second section 3512. For example, the sealing structure and the second section 3512 may be disposed coaxially.

Exemplarily, a sealing hole 352 is provided on the surface of the adapter structure 35 facing away from the cavity body 34. The sealing hole 352 communicates with the second section 3512. The cooling cavity body 3 further includes a sealing screw 37 that is sealingly screwed into the sealing hole 352. When the cooling medium in the cooling cavity 10 needs to be discharged, the sealing screw 37 is detached from the sealing hole 352. In this case, the cooling medium in the cooling cavity 10 flows out through the first section 3511, the second section 3512, and the sealing hole 352 so that the cooling cavity body 3 is emptied.

In one or more embodiments, the cavity body 34 and the conductive terminal 1 in this embodiment may be coaxially connected to each other or may not be coaxially connected to each other, which is not limited in this embodiment. The cavity body 34 and the cable 2 may be coaxially connected to each other or may not be coaxially connected to each other, which is not limited in this embodiment.

In the terminal assembly 100 provided in this embodiment, the cylindrical support structure 4 is disposed at the center of the cable 2 to ensure the smoothness with which the cooling medium flows in the cable 2. The cooling cavity body 3 made of the metal material is provided so that the pressure resistance of the terminal assembly 100 can be effectively improved. The connecting portion 122 of the conductive terminal 1 and the conductive portion 22 of the cable 2 are located in the cooling cavity 10. Thus, the cooling effect of the cooling medium on the conductive portion 22 and the connecting portion 122 is improved, and the risk of the excessively high temperature at the joint between the conductive portion 22 and the connecting portion 122 is reduced, thereby increasing the maximum overcurrent that the terminal assembly 100 can bear. Furthermore, the charging efficiency of the liquid-cooled charging system using the terminal assembly 100 is improved.

### Embodiment Two

This embodiment provides a terminal assembly 100, which differs from embodiment one in the shape of a plug-in end 11.

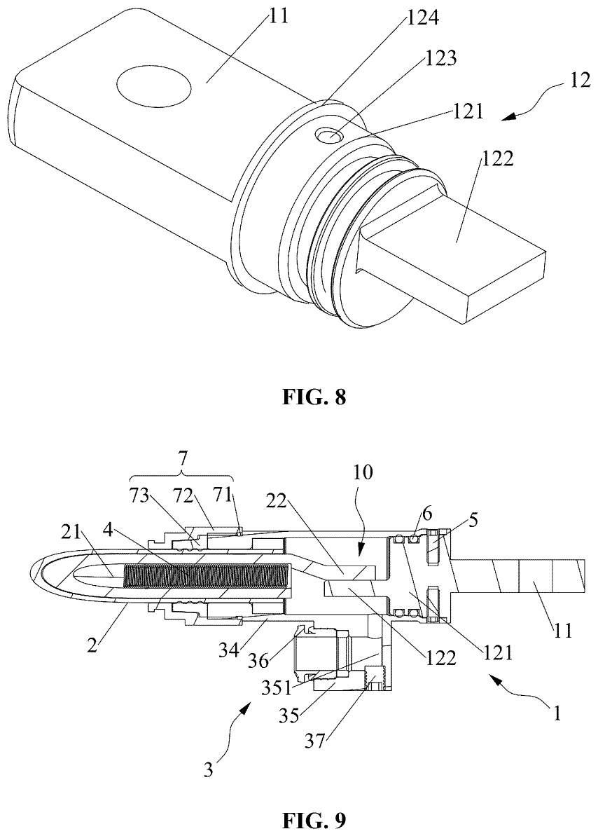

As shown in FIGS. 7 to 9, the plug-in end 11 of the conductive terminal 1 in this embodiment is in the shape of a cuboid instead of a cylindrical shape to adapt to the case where the slot is in the shape of a cuboid.

In one or more embodiments, the plug-in end 11 in this embodiment may further be provided with a hole (not shown in the figure).

Other structures in this embodiment are similar to the corresponding structures in embodiment one and have similar beneficial effects, and the details are not described herein again in this embodiment.

### Embodiment Three

This embodiment further provides a liquid-cooled charging system. The liquid-cooled charging system includes the terminal assembly 100 in embodiment one and/or embodiment two. The terminal assembly 100 of the liquid-cooled charging system in this embodiment can bear a relatively large maximum overcurrent so that the liquid-cooled charging system can have relatively high charging efficiency.

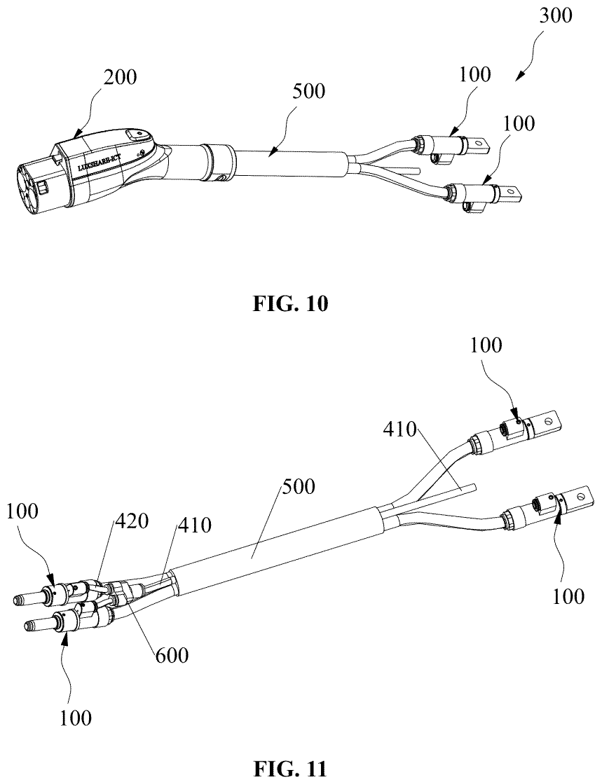

For example, FIGS. 10 and 11 show the liquid-cooled charging system in this embodiment. The liquid-cooled charging system includes a head structure 200 and a tail structure 300. The head structure 200 and the tail structure 300 each include at least one terminal assembly 100. The cable 2 of the terminal assembly 100 of the head structure 200 is electrically connected to the cable 2 of the terminal assembly 100 of the tail structure 300. In addition, cooling channels 21 of the two connected cables 2 communicate with one another to form a cooling loop.

For example, as shown in FIG. 11, the head structure 200 includes two terminal assemblies 100, and the tail structure 300 also includes two terminal assemblies 100. In one or more embodiments, each of the two terminal assemblies 100 of the head structure 200 may be the terminal assembly 100 in embodiment one, and each of the two terminal assemblies 100 of the tail structure 300 may be the terminal assembly 100 in embodiment two.

In an embodiment, the liquid-cooled charging system further includes a confluence cavity 500. The confluence cavity 500 is disposed between the head structure 200 and the tail structure 300. For example, the confluence cavity 500 may be sleeved outside the cables 2. The cooling inlet 31 of each terminal assembly 100 communicates with the confluence cavity 500 through a tube (not shown in the figure) so that the confluence cavity 500, the tube, the cooling cavity 10, and the cooling channel 21 form a cooling loop.

For example, two ends of the confluence cavity 500 are each connected to one main tube 410. The cooling inlets 31 of the two terminal assemblies 100 of the head structure 200 are connected to one main tube 410 via a tee 600 and two branch tubes 420. The cooling inlets 31 of the two terminal assemblies 100 of the tail structure 300 are connected to the other main tube 410 via a tee 600 and two branch tubes 420.

In one or more embodiments, the liquid-cooled charging system in this embodiment may be a charging gun.

It is to be noted that the preceding are only preferred embodiments of the present disclosure and technical principles used therein. It is to be understood by those skilled in the art that the present disclosure is not limited to the embodiments described herein. Those skilled in the art can make various apparent modifications, adaptations, and substitutions without departing from the scope of the present disclosure. Therefore, although the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A terminal assembly, comprising:
a conductive terminal having a plug-in end and a connecting end;
a cable electrically connected to the connecting end; and
a cooling cavity body, wherein the cooling cavity body has a cooling inlet, one end of the cooling cavity body is sealingly sleeved on the connecting end, and the other end of the cooling cavity body is sealingly sleeved on an end of the cable for connecting the connecting end;
wherein the conductive terminal, the cable, and the cooling cavity body mate with one another to form a cooling cavity communicating with the cooling inlet, and a cooling medium is disposed in the cooling cavity.

2. The terminal assembly according to claim 1, wherein the cable is provided with a cooling channel, the cooling channel has a channel opening on a surface of the cable, and the channel opening is provided in a portion of the cable located in the cooling cavity body and communicates with the cooling cavity.

3. The terminal assembly according to claim 2, further comprising a support structure disposed in the cooling channel, wherein the support structure is provided with a support through hole communicating with the cooling channel and is configured to support the cable.

4. The terminal assembly according to claim 1, wherein the connecting end comprises a body portion and a connecting portion, the cooling cavity body is sealingly sleeved on the body portion, the body portion, the cable, and the cooling cavity body mate with one another to form the cooling cavity communicating with the cooling inlet, and the connecting portion is located in the cooling cavity.

5. The terminal assembly according to claim 4, wherein a conductive portion is disposed at the end of the cable facing the conductive terminal, the conductive portion and the connecting portion are stacked and electrically connected to each other, and the conductive portion is located in the cooling cavity.

6. The terminal assembly according to claim 1, wherein the cooling cavity body is provided with a mounting hole, a screw hole mating with the mounting hole is provided at the connecting end, the terminal assembly further comprises a connecting bolt, and the connecting bolt passes through the mounting hole and is screwed into the screw hole to connect the cooling cavity body to the connecting end.

7. The terminal assembly according to claim 6, further comprising a first sealing assembly, wherein the first sealing assembly is sleeved on the connecting end and is configured to seal a gap between an outer peripheral surface of the connecting end and an inner peripheral surface of the cooling cavity body, and the first sealing assembly is disposed on a side of the connecting bolt facing the cooling cavity.

8. The terminal assembly according to claim 1, wherein a stop portion is provided on an outer peripheral surface of the connecting end, and the stop portion is used for abutting against an end surface of the end of the cooling cavity body to limit a relative position between the cooling cavity body and the conductive terminal.

9. The terminal assembly according to claim 1, wherein the terminal assembly further comprises a second sealing assembly, the second sealing assembly is sleeved on the cable and located at a joint between the cable and the cooling cavity body, a limit protrusion is provided on an inner wall of one end of the second sealing assembly, the other end of the second sealing assembly is connected to the cable, a limit groove is provided on an outer wall of the cooling cavity body, and the limit protrusion is engaged in the limit groove.

10. The terminal assembly according to claim 1, wherein a stop portion is provided on an outer peripheral surface of the connecting end, and the stop portion is used for abutting against an end surface of the end of the cooling cavity body to limit a relative position between the cooling cavity body and the conductive terminal; and
the terminal assembly further comprises a second sealing assembly, the second sealing assembly is sleeved on the cable and located at a joint between the cable and the cooling cavity body, a limit protrusion is provided on an inner wall of one end of the second sealing assembly, the other end of the second sealing assembly is connected to the cable, a limit groove is provided on an outer wall of the cooling cavity body, and the limit protrusion is engaged in the limit groove.

11. The terminal assembly according to claim 1, wherein the cooling cavity body comprises a cavity body, an adapter structure, and a sealing joint, one end of the cavity body is sealingly sleeved on the connecting end, the other end of the cavity body is sealingly sleeved on the cable, and the cavity body, the conductive terminal, and the cable mate with one another to form the cooling cavity; and
the adapter structure is connected to a side of the cavity body, the adapter structure has a connecting flow channel communicating with the cooling cavity, the sealing joint is sealingly disposed at a flow channel opening of the connecting flow channel facing away from the cooling cavity, and the cooling inlet is disposed at the sealing joint and communicates with the connecting flow channel.

12. The terminal assembly according to claim 2, wherein the connecting end comprises a body portion and a connecting portion, the cooling cavity body is sealingly sleeved on the body portion, the body portion, the cable, and the cooling cavity body mate with one another to form the cooling cavity communicating with the cooling inlet, and the connecting portion is located in the cooling cavity.

13. The terminal assembly according to claim 3, wherein the connecting end comprises a body portion and a connecting portion, the cooling cavity body is sealingly sleeved on the body portion, the body portion, the cable, and the cooling cavity body mate with one another to form the cooling cavity communicating with the cooling inlet, and the connecting portion is located in the cooling cavity.

14. The terminal assembly according to claim 2, wherein the cooling cavity body is provided with a mounting hole, a screw hole mating with the mounting hole is provided at the connecting end, the terminal assembly further comprises a connecting bolt, and the connecting bolt passes through the mounting hole and is screwed into the screw hole to connect the cooling cavity body to the connecting end.

15. The terminal assembly according to claim 3, wherein the cooling cavity body is provided with a mounting hole, a screw hole mating with the mounting hole is provided at the connecting end, the terminal assembly further comprises a connecting bolt, and the connecting bolt passes through the mounting hole and is screwed into the screw hole to connect the cooling cavity body to the connecting end.

16. The terminal assembly according to claim 2, wherein a stop portion is provided on an outer peripheral surface of the connecting end, and the stop portion is used for abutting against an end surface of the end of the cooling cavity body to limit a relative position between the cooling cavity body and the conductive terminal; and/or
the terminal assembly further comprises a second sealing assembly, the second sealing assembly is sleeved on the cable and located at a joint between the cable and the cooling cavity body, a limit protrusion is provided on an inner wall of one end of the second sealing assembly, the other end of the second sealing assembly is connected to the cable, a limit groove is provided on an outer wall of the cooling cavity body, and the limit protrusion is engaged in the limit groove.

17. The terminal assembly according to claim 3, wherein a stop portion is provided on an outer peripheral surface of the connecting end, and the stop portion is used for abutting against an end surface of the end of the cooling cavity body to limit a relative position between the cooling cavity body and the conductive terminal; and/or
the terminal assembly further comprises a second sealing assembly, the second sealing assembly is sleeved on the cable and located at a joint between the cable and the cooling cavity body, a limit protrusion is provided on an inner wall of one end of the second sealing assembly, the other end of the second sealing assembly is connected to the cable, a limit groove is provided on an outer wall of the cooling cavity body, and the limit protrusion is engaged in the limit groove.

18. The terminal assembly according to claim 2, wherein the cooling cavity body comprises a cavity body, an adapter structure, and a sealing joint, one end of the cavity body is sealingly sleeved on the connecting end, the other end of the cavity body is sealingly sleeved on the cable, and the cavity body, the conductive terminal, and the cable mate with one another to form the cooling cavity; and
the adapter structure is connected to a side of the cavity body, the adapter structure has a connecting flow channel communicating with the cooling cavity, the sealing joint is sealingly disposed at a flow channel opening of the connecting flow channel facing away from the cooling cavity, and the cooling inlet is disposed at the sealing joint and communicates with the connecting flow channel.

19. The terminal assembly according to claim 3, wherein the cooling cavity body comprises a cavity body, an adapter structure, and a sealing joint, one end of the cavity body is sealingly sleeved on the connecting end, the other end of the cavity body is sealingly sleeved on the cable, and the cavity body, the conductive terminal, and the cable mate with one another to form the cooling cavity; and
the adapter structure is connected to a side of the cavity body, the adapter structure has a connecting flow channel communicating with the cooling cavity, the sealing joint is sealingly disposed at a flow channel opening of the connecting flow channel facing away from the cooling cavity, and the cooling inlet is disposed at the sealing joint and communicates with the connecting flow channel.

20. A liquid-cooled charging system, comprising a terminal assembly; wherein the terminal assembly comprises:
a conductive terminal having a plug-in end and a connecting end;
a cable electrically connected to the connecting end; and
a cooling cavity body, wherein the cooling cavity body has a cooling inlet, one end of the cooling cavity body is sealingly sleeved on the connecting end, and the other end of the cooling cavity body is sealingly sleeved on an end of the cable for connecting the connecting end;
wherein the conductive terminal, the cable, and the cooling cavity body mate with one another to form a cooling cavity communicating with the cooling inlet, and a cooling medium is disposed in the cooling cavity.
